(19) United States
(12) Patent Application Publication
(10) Pub. No.: US 2014/0219041 A1
(43) Pub. Date: Aug. 7, 2014

(54) STORAGE DEVICE AND DATA PROCESSING METHOD THEREOF

(71) Applicant: SAMSUNG ELECTRONICS CO., LTD., Suwon-si (KR)

(72) Inventors: SANG-MOK KIM, Seoul (KR); Kyung-Ho Kim, Seoul (KR); Hyun-Chul Park, Ansan-si (KR); Jin-Seok Kim, Seoul (KR)

(73) Assignee: SAMSUNG ELECTRONICS CO., LTD., Suwon-si (KR)

(21) Appl. No.: 14/166,323

(22) Filed: Jan. 28, 2014

(30) Foreign Application Priority Data
Feb. 5, 2013 (KR) 10-2013-0012942

(51) Int. Cl. G11C 29/00

(52) U.S. Cl. CPC G11C 29/00
USPC 365/200

(57) ABSTRACT

A method of processing data in a storage device includes writing first data to a data storage unit of the storage device upon receiving the first data from an external host of the storage device, outputting a message to the external host indicating completion of writing the first data to the data storage unit, and determining whether a first data unit included in the first data is redundant in the data storage unit. Determining whether the first data unit is redundant is performed subsequent to or in parallel with writing the first data to the data storage unit.

### CROSS-REFERENCE TO RELATED APPLICATIONS

This application claims priority under 35 U.S.C. §119 to Korean Patent Application No. 10-2013-0012942, filed on Feb. 5, 2013, the disclosure of which is incorporated by reference herein in its entirety.

### TECHNICAL FIELD

Exemplary embodiments of the present invention relate to a storage device and a method of processing data in the storage device, and more particularly, to a storage device processing and storing duplicate data, and a method of processing the data in the storage device.

### DISCUSSION OF THE RELATED ART

Storage devices that store data are used in various electronic devices. For example, storage devices include hard disks used in personal computers, servers, semiconductor memory devices used in portable electronic devices, etc. Other than a processor and a storage device in an electronic device, other components may process data after accessing the storage device to write or read data, allowing necessary operations to be performed. A component having access to the storage device that writes and/or reads data may be referred to as a host. For example, the host may include a semiconductor chip such as a processor and a computing system accessing a portable storage device.

The host may require a large data capacity storage device to store a large amount of data, as well as a storage device having a fast response time so that data may be quickly written and read to and from the storage device in response to requests from the host. The storage device may include a controller therein, and the controller may store or read data in or from a data storage space in response to a host request.

### SUMMARY

Exemplary embodiments of the present invention provide a storage device processing and storing duplicate data, improving a response speed to a request from a host, and a method of processing data in the storage device.

According to an exemplary embodiment of the present invention, a method of processing data in a storage device includes, upon receiving first data from an external host of the storage device, writing the first data to a data storage unit of the storage device, once the writing of the first data is completed, outputting a message to the external host that indicates a completion of a writing request, and determining whether a first data unit that is included in the first data is redundant, wherein the determining is performed after or in parallel with the writing of the first data.

Determining whether the first data unit is redundant may include generating a hash value of the first data unit, determining whether the first data unit is redundant based on the hash value of the first data unit and information relating to a hash value of a second data unit included in second data received prior to the first data and stored in the data storing unit, and writing redundancy information corresponding to the first data unit to a redundancy information storage unit of the storage device according to a result of the determining.

Determining whether the first data unit is redundant may further include, when it is determined that the first data unit is redundant, allowing a physical address of mapping information corresponding to the first data unit to be identical to a physical address of mapping information corresponding to the second data unit.

The data storage unit may include flash memory, further including processing an area in which the first data unit is stored as an invalid area to perform garbage collection or wear leveling when it is determined that the first data unit in the data storage unit is redundant based on the redundancy information of the first data unit written to the redundancy information storage unit.

The method may further include performing a deduplication operation, wherein performing the deduplication operation may include erasing an area in which the first data unit is stored in the data storage unit based on the redundancy information of the first data unit stored in the redundancy information storage unit, and updating the redundancy information of the first data unit.

Performing the deduplication operation may further include, when the first data unit is redundant, changing a physical address of mapping information corresponding to the first data unit to a physical address of mapping information corresponding to a second data unit redundant to the first data unit.

Performing the deduplication operation may progress when there is no additional request from the external host after the outputting of the message and the determining of whether the first data unit is redundant are completed.

According to an exemplary embodiment of the present invention, a storage device includes a hashing unit generating a hash value of a first data unit included in first data received from an external host, a data storage unit storing second data received prior to the first data, a hash information storage unit storing information on a hash value of at least one second data unit included in the second data, a redundancy information storage unit storing redundancy information of the at least one second data unit, and a control unit performing an operation of determining redundancy of the first data unit when receiving the first data from the external host. The operation of determining redundancy of the first data unit is performed after or in parallel with an operation of writing the first data to the data storing unit. The operation of determining redundancy of the first data unit includes an operation of determining whether the first data unit is redundant based on information on the hash value of the at least one second data unit and the hash value of the first data unit, and an operation of writing redundancy information of the first data unit to the redundancy information storing unit.

The control unit may further perform an operation of erasing an area where the first data unit is stored in the data storage unit based on the redundancy information of the first data unit written to the redundancy information storage unit and a deduplication operation of updating the redundancy information of the first data unit.

The control unit may perform the deduplication operation when there is no additional request from the external host after the storing by the data storage unit and the operation of determining redundancy of the first data unit are completed.

The control unit may change a physical address of mapping information corresponding to the first data unit to a physical address of mapping information corresponding to the second data unit during the redundancy determining operation, when it is determined that the first data unit is redundant.

The control unit may change a physical address of mapping information corresponding to the first data unit to a physical address of mapping information corresponding to a second data unit redundant to the first data unit during the deduplication operation, when it is determined that the first data unit is redundant.

The data storage unit may include flash memory, and the control unit, during garbage collection or wear leveling of the flash memory, may process an area in which the first data unit is stored as an invalid area when it is determined that the first data unit is redundant according to the redundancy information of the first data unit written to the redundancy information storage unit.

The control unit may perform an operation of storing information on the hash value of the first data unit in the hash information storage unit during the redundancy determining operation when it is determined that the first data unit is not redundant.

The redundancy information storage unit may further store size information of the first data unit and the at least one second data unit.

According to an exemplary embodiment of the present invention, a method of processing data in a storage device includes writing first data to a data storage unit of the storage device upon receiving the first data from an external host of the storage device, outputting a message to the external host indicating completion of writing the first data to the data storage unit, and determining whether a first data unit included in the first data is redundant in the data storage unit. Determining whether the first data unit is redundant is performed subsequent to or in parallel with writing the first data to the data storage unit.

Determining whether the first data unit is redundant may include generating a hash value of the first data unit, determining whether the first data unit is redundant based on the hash value of the first data unit and information relating to a hash value of a second data unit included in second data received prior to the first data and stored in the data storage unit, and writing redundancy information corresponding to the first data unit and indicating whether the first data unit is redundant to a redundancy information storage unit of the storage device according to a result of determining whether the first data unit is redundant.

The method may further include modifying a physical address of mapping information corresponding to the first data unit to be identical to a physical address of mapping information corresponding to the second data unit upon determining that the first data unit is redundant with respect to the second data unit.

The method may further include performing garbage collection or wear leveling in an invalid area of the data storage unit in which the first data unit is stored upon determining that the first data unit is redundant based on the redundancy information corresponding to the first data unit, wherein the data storage unit comprises flash memory.

The method may further include performing a deduplication operation, wherein the deduplication operation comprises erasing an area in which the first data unit is stored in the data storage unit based on the redundancy information corresponding to the first data unit, and updating the redundancy information corresponding to the first data unit.

Performing the deduplication operation may further include changing a physical address of mapping information corresponding to the first data unit to a physical address of mapping information corresponding to the second data unit upon determining that the first data unit is redundant with respect to the second data unit.

The deduplication operation may progress to additional data units when a request from the external host is not pending after outputting the message and after determining whether the first data unit is redundant.

Additional operations may not be performed between writing the first data to the data storage unit and determining whether the first data unit is redundant, when determining whether the first data unit is redundant is performed subsequent to writing the first data to the data storage unit.

According to an exemplary embodiment of the present invention, a storage device includes a hashing unit configured to generate a hash value of a first data unit included in first data received from an external host, a data storage unit configured to store second data received prior to the first data, a hash information storage unit configured to store information relating to a hash value of at least one second data unit included in the second data, a redundancy information storage unit configured to store redundancy information corresponding to the at least one second data unit and indicating whether the at least one second data unit is redundant, and a control unit configured to determine redundancy of the first data unit upon receiving the first data from the external host. Determining the redundancy of the first data unit is performed subsequent to or in parallel with writing the first data to the data storage unit. Determining the redundancy of the first data unit includes determining whether the first data unit is redundant based on the information relating to the hash value of the at least one second data unit and the hash value of the first data unit. The control unit is further configured to write redundancy information corresponding to the first data unit and indicating whether the first data unit is redundant to the redundancy information storage unit upon determining the redundancy of the first data unit.

The control unit may further be configured to erase an area in which the first data unit is stored in the data storage unit based on the redundancy information corresponding to the first data unit, and perform a deduplication operation comprising updating the redundancy information corresponding to the first data unit.

The control unit may be configured to perform the deduplication operation when a request from the external host is not pending after storing the second data and determining the redundancy of the first data unit.

The control unit may further be configured to change a physical address of mapping information corresponding to the first data unit to a physical address of mapping information corresponding to the at least one second data unit while determining the redundancy of the first data unit, upon determining that the first data unit is redundant.

The control unit may further be configured to change a physical address of mapping information corresponding to the first data unit to a physical address of mapping information corresponding to the at least one second data unit during the deduplication operation, upon determining that the first data unit is redundant with respect to the at least one second data unit.

The data storage unit may include flash memory, and the control unit may further be configured to perform garbage collection or wear leveling in an invalid area of the flash memory in which the first data unit is stored upon determining that the first data unit is redundant based on the redundancy information corresponding to the first data unit.

The control unit may further be configured to store information relating to the hash value of the first data unit in the hash information storage unit while determining the redundancy of the first data unit upon determining that the first data unit is not redundant.

The redundancy information storage unit may further be configured to store size information of the first data unit and the at least one second data unit.

Additional operations may not be performed between writing the first data to the data storage unit and determining whether the first data unit is redundant, when determining whether the first data unit is redundant is performed subsequent to writing the first data to the data storage unit.

According to an exemplary embodiment of the present invention, a method of processing data in a storage device includes writing first data to a data storage unit of the storage device upon receiving the first data from an external host of the storage device, determining whether a first data unit included in the first data is redundant in the data storage unit, wherein determining whether the first data unit is redundant is performed subsequent to or simultaneous with writing the first data to the data storage unit, and removing the first data unit from the data storage unit during an idle time of the storage device upon determining that the first data unit is redundant, wherein a request from the external host is not pending during the idle time.

Additional operations may not be performed between writing the first data to the data storage unit and determining whether the first data unit is redundant, when determining whether the first data unit is redundant is performed subsequent to writing the first data to the data storage unit.

Determining whether the first data unit is redundant may include generating a hash value of the first data unit, determining whether the first data unit is redundant based on the hash value of the first data unit and information relating to a hash value of a second data unit included in second data received prior to the first data and stored in the data storage unit, and writing redundancy information corresponding to the first data unit and indicating whether the first data unit is redundant to a redundancy information storage unit of the storage device according to a result of determining whether the first data unit is redundant.

### BRIEF DESCRIPTION OF THE DRAWINGS

The above and other features of the present invention will become more apparent by describing in detail exemplary embodiments thereof with reference to the accompanying drawings, in which:

FIG. 1 is a block diagram illustrating a configuration of a storage device, according to an exemplary embodiment of the present invention.

FIG. 2 illustrates an operation of a hashing unit of FIG. 1, according to an exemplary embodiment of the present invention.

FIGS. 3A and 3B illustrate a method of removing data redundancy in a storage device, according to an exemplary embodiment of the present invention.

FIG. 4 illustrates an operation of determining data redundancy, performed by a storage device, according to an exemplary embodiment of the present invention.

FIGS. 5A and 5B illustrate exemplary embodiments of a hashing unit, a hash information storage unit, and a control unit of FIG. 1.

FIGS. 6A and 6B illustrate an operation of removing data redundancy in a storage device, according to an exemplary embodiment of the present invention.

FIG. 7 illustrates an operation of removing data redundancy using a redundancy information storage unit of a storage device, according to an exemplary embodiment of the present invention.

FIG. 8 is a flowchart illustrating a method of removing data redundancy in a storage device, according to an exemplary embodiment of the present invention.

FIG. 9 illustrates a method of determining data redundancy in a storage device, according to an exemplary embodiment of the present invention.

FIGS. 10A and 10B illustrate a comparison of the methods of removing data redundancy in a storage device of FIGS. 3A and 3B, and FIG. 9, according to exemplary embodiments of the present invention.

FIG. 11 is a block diagram illustrating a computing system including a storage device and a host, according to an exemplary embodiment of the present invention.

FIG. 12 is a block diagram illustrating a memory card, according to an exemplary embodiment of the present invention.

### DETAILED DESCRIPTION OF THE EXEMPLARY EMBODIMENTS

Exemplary embodiments of the present invention will be described more fully hereinafter with reference to the accompanying drawings. Like reference numerals may refer to like elements throughout the accompanying drawings.

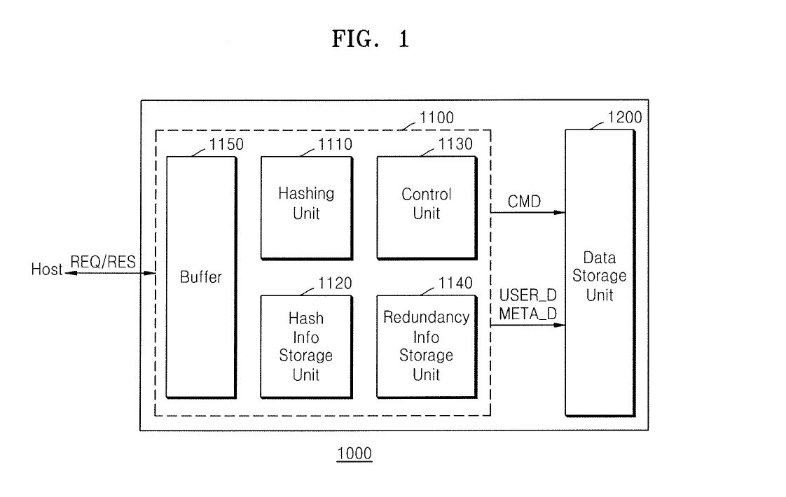

FIG. 1 is a block diagram illustrating a configuration of a storage device, according to an exemplary embodiment of the present invention. The storage device 1000 may include, for example, a controller 1100 and a data storage unit 1200. The controller 1100 may communicate with an external host of the storage device 1000, and may receive a request from a host for writing/reading data. The controller 1100 controls the data storage unit 1200 to perform an operation corresponding to a request REQ of a host. The controller 110 may control the data storage unit 1200 via a command signal CMD. The data storage unit 1200 may store data that a host stores, and data for managing the data that the host stores. Herein, the data that a host stores may be referred to as user data USER_D and the data for managing the data that the host stores may be referred to as metadata META_D. Additionally, the controller 1100 may transmit a response RES to a host that includes a message notifying the host of the completion of an operation corresponding to the request REQ of a host, a state of a storage device, and data that a host requests to read.

As shown in FIG. 1, the controller 1100 may include, for example, a hashing unit 1110, a hash information storage unit 1120, a control unit 1130, a redundancy information storage unit 1140, and a buffer 1150. The buffer 1150 may temporarily store first data included in a request that a host transmits for writing data to the storage device 1000. For example, when the storage device 1000 is a nonvolatile storage device that retains data even when no power is supplied, writing data may take a relatively long time due to the nonvolatile characteristic of the data storage unit 1200. Additionally, as the storage capacity of the data storage unit 1200 becomes larger, writing data may take longer due to the amount of time required for accessing the space in the storage unit 1200 where the data is to be written. Accordingly, as shown in FIG. 1, the storage device 1000 may include a buffer 1150 having a faster data writing and reading speed relative to the data storage unit 1200. For example, the buffer 1150 may be a volatile memory device including a DRAM or SRAM. The first data may be temporarily stored in the buffer 1150, and then may be copied to the data storage unit 1200.

According to an exemplary embodiment of the present invention, the storage device 1000 may receive first data from a host, and the first data may be divided by at least one data unit. For example, the data unit may include a block, a sector, and a page of flash memory. The hashing unit 1110 may generate a hash value of a first data unit as an arbitrary data unit of the first data. The size of the data unit corresponding to each hash value that the hashing unit 1110 generates may be the same or different. The hash value may be the result value of a hash-function into which a data unit has been input. For example, the hashing unit 1110 may generate a hash value of a first data unit by using the first data unit as an input of a hash-function. The hash-function is a function that matches different input data to different hash values. If two compared hash values are different, it is determined that two pieces of input data corresponding to those two compared hash values are also different. An arbitrary hash-function may be used to generate a hash value of the first data unit. For example, the hash-function may include a Message-Digest algorithm 5 (MD5), a Secure Hash Algorithm such as SHA-1, SHA-2 (e.g., SHA-224, SHA-256, SHA-384, and SHA-512), and SHA-3.

According to an exemplary embodiment of the present invention, the hash information storage unit 1120 may store information relating to a hash value of data stored in the data storage unit 1200. For example, the hash information storage unit 1120 may store information relating to a hash value of a second data unit included in second data stored in the data storage unit 1200. The hash information storage unit 1120 may store a hash value of the second data unit or, functioning as a look-up table, may store a predetermined value at a location defined by an address corresponding to a hash value of the second data unit. An exemplary embodiment of the hash information storage unit 1120 will be described in further detail below.

According to an exemplary embodiment of the present invention, the control unit 1130 may control other components in the controller 1100. For example, the control unit 1130 may control reading of the first data stored in the buffer 1150 and writing of the read first data to the data storage unit 1200. Additionally, by comparing a hash value of the first data unit with a hash value of the second data unit (or information relating to a hash value of the second data unit), the redundancy of the first and second data units may be determined based on whether hash values are identical to each other. According to a determination result, redundancy information of the first data unit may be stored in the redundancy information storage unit 1140. Furthermore, if the first data unit is not redundant with respect to data units that are included in the data stored in the data storage unit 1200, the control unit 1130 may write a hash value of the first data unit or information relating to a hash value of the first data unit to the hash information storage unit 1120.

Furthermore, the control unit 1130 may perform a redundancy removal operation, which may also be referred to as a deduplication operation, on the redundant data stored in the data storage unit 1200, on the basis of the redundancy information stored in the redundancy information storage unit 1140. For example, the control unit 1130 may obtain redundancy information of the data unit that is included in the data stored in the data storage unit 1200 from the redundancy information storage unit 1140, and if the data unit is redundant in the data storage unit 1200, an area in which the redundant data unit is stored may be erased.

According to an exemplary embodiment of the present invention, the redundancy information storage unit 1140 may store redundancy information relating to data units that are included in data stored in the data storage unit 1200. For example, the redundancy information storage unit 1140 may store the information that indicates the redundancy of a data unit by using one bit. Furthermore, if the sizes of the data units into which the hashing unit 1110 divides the data are not constant, the redundancy information storage unit 1140 may store size information of a data unit in addition to the redundancy of a data unit.

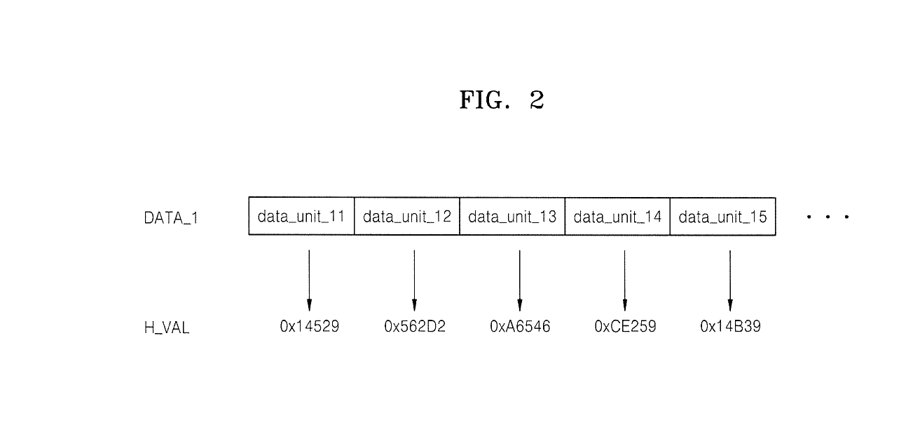

FIG. 2 illustrates an operation of the hashing unit 1110 of FIG. 1, according to an exemplary embodiment of the present invention. For example, the hashing unit 1110 may generate hash values of data units data_unit_{—}11 to data_unit_{—}15 that are included in first data DATA_{—}1 received from an external host. A hash value that the hashing unit 1110 generates may be input to the control unit 1130 or the hash information storage unit 1120 to determine the redundancy of a data unit that is included in second data stored in the data storage unit 1200, according to an exemplary embodiment of the present invention.

As shown in FIG. 2, the hashing unit 1110 may generate hash values respectively corresponding to the data units data_unit_{—}11 to data_unit_{—}15. For example, the hashing unit 1110 may generate a hash value 0x14529 using the data unit data_unit_{—}11 as an input of a hash-function. The control unit 1130 determines whether any data stored in the data storage unit 1200 has a hash value identical to the hash value 0x14529 generated by the hashing unit 1110. As shown in FIG. 2, the hashing unit may further generate hash values 0x562D2, 0xA6546, 0xCE259 and 0x14B39 corresponding to data units data_unit_{—}12, data_unit_{—}13, data_unit_{—}14 and data_unit_{—}15, respectively.

Moreover, according to an exemplary embodiment of the present invention, although the data units data_unit_{—}11 to data_unit_{—}15 shown in FIG. 2 are all the same size, the sizes of the data units are not limited thereto. For example, the sizes of some or all of the data units may be different. If the sizes of the data units data_unit_{—}11 to data_unit_{—}15 are different, the redundancy information storage unit 1140 may further store size information of each of the data units data_unit_{—}11 to data_unit_{—}15.

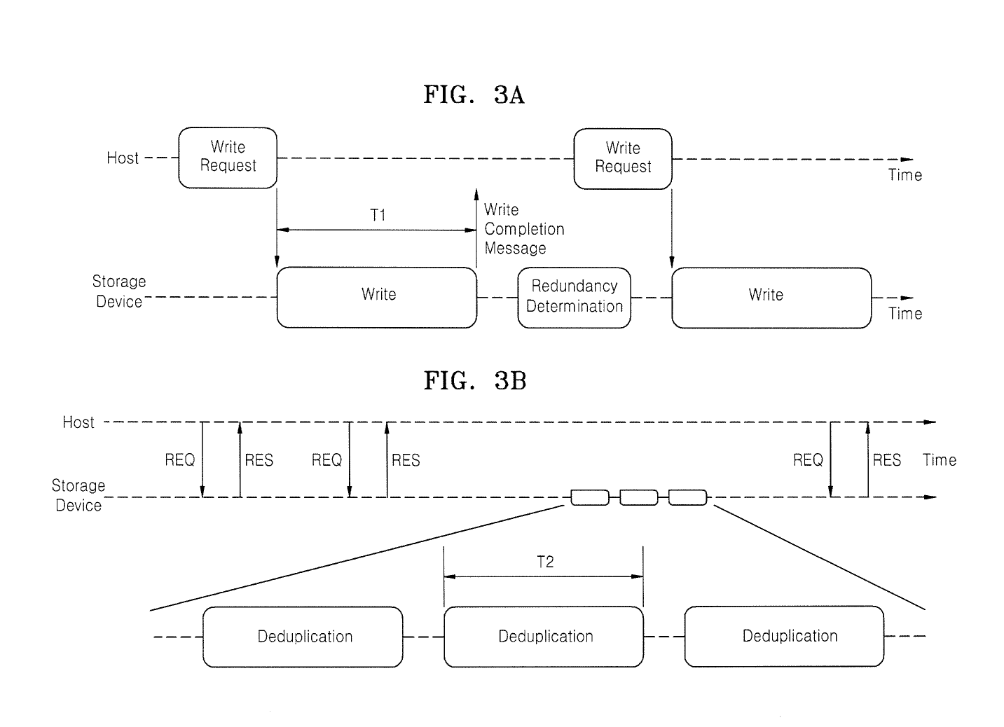

FIGS. 3A and 3B illustrate a method of removing data redundancy in a storage device, according to an exemplary embodiment of the present invention. According to an exemplary embodiment of the present invention, upon receiving a request for writing first data from a host, the storage device 1000 of FIG. 1 writes first data. The storage device 1000 may be in a state in which it can transmit a message notifying the host of the completion of a writing operation, or a state in which it receives a new request from a host after writing first data. Moreover, after writing the first data, the storage device 1000 may perform an operation of determining whether redundancy exists between the first data and the second data that the storage device 1000 stored previously, and may also store a determination result in a separate storage space. Based on the determination result stored in the separate storage space, if it is determined that the first data is redundant, the storage device 1000 may perform an operation of erasing the first data during an idle time.

FIG. 3A illustrates an operation that the storage device 1000 performs when a host transmits a request for writing data, according to an exemplary embodiment of the present invention. As shown in FIG. 3A, the storage device 1000 of FIG. 1 may receive a request for writing the first data from the host. The control unit 1130 in the storage device 1000 may write the first data to the data storage unit 1200, and may transmit a completion message for notifying the host that the first data writing operation has been completed.

A time from when the storage device 1000 receives a request from the host to when the storage device 1000 either transmits the completion message of an operation requested by the host or enters into a standby state to receive a new request from the host is called a response time of the storage device 1000. The host may perform an operation independently from the storage device 1000 during a response time of the storage device 1000. Since the host waits until after a response time of the storage device 1000 to transmit a new request to the storage device 1000, as the response time of the storage device 1000 increases, an execution time of an operation that the host performs also increases. As a result, the speed of a system including the host may deteriorate.

As shown in FIG. 3A, the response time of the storage device 1000 may include a time for writing the first data, and is indicated by T1 in FIG. 3A. Since a time for determining the redundancy of the first data is not included in the response time T1 of the storage device 1000, the storage device 1000 may have a relatively short response time.

Moreover, according to an exemplary embodiment of the present invention, after writing the first data, the storage device 1000 of FIGS. 3A and 3B may perform an operation of determining the redundancy of the first data. After writing the first data to the data storage unit 1200, the control unit 1130 in the storage device 1000 may perform an operation of determining the redundancy of the first data by using the hashing unit 1110, the hash information storage unit 1120, and the redundancy information storage unit 1140. The process of determining the redundancy of the first data is described in further detail below. The process of receiving a write request from the host, performing the write operation, and determining redundancy may be repeated, as shown in FIG. 3A. In exemplary embodiments, the operation of determining redundancy may be performed immediately subsequent to, or substantially immediately subsequent to writing the data to the storage unit 1200. That is, the operation of determining redundancy may be the next operation performed subsequent to writing the data to the storage unit 1200. For example, no other operations may exist between the operation of writing the data to the storage unit 1200 and the operation of determining redundancy.

FIG. 3B illustrates an operation that the storage device 1000 performs during an idle time, according to an exemplary embodiment of the present invention. As shown in FIG. 3B, during an idle time of the storage device 1000, the control unit 1130 of FIG. 1 may perform an operation of selectively removing the redundant first data stored in the data storage unit 1200 according to redundancy information relating to the first data stored in the redundancy information storage unit 1140. For example, the control unit 1130 may erase an area in which the first data unit is stored in the data storage unit 1200 when the first data unit is redundant, as determined according to redundancy information of the first data unit included in the first data. Moreover, the control unit 1130 may perform an update operation to indicate that the redundancy information of the first data unit is no longer applicable once the redundant data has been removed.

The storage device 1000 may perform operations of effectively managing stored data during an idle time. For example, when the data storage unit 1200 in the storage device 1000 is configured with flash memory, it may perform garbage collection during an idle time. Such operations that the storage device 1000 performs during an idle time may be referred to as background operations.

According to an exemplary embodiment, since the storage device 1000 cannot predict the timing at which the host transmits a request to the storage device 1000, when the storage device 1000 receives a request from the host during execution of a background operation, the storage device 1000 may stop the execution of the background operation, return to a state prior to execution of the background operation, and then process the host's request. Alternatively, the storage device 1000 may complete the background operation currently being executed, and then start an operation corresponding to the request received from the host. Accordingly, when the storage device 1000 receives a request from the host during execution of a background operation, a response time of the storage device 1000 for responding to the host's request may be longer than usual. In addition, as the time required for the storage device 1000 to perform a background operation increases, the possibility that the host transmits a request during execution of a background operation increases. As shown in FIG. 3B, the time taken for the storage device 1000 to remove the redundant first data (e.g., deduplication) during an idle time is indicated by T2. Since an operation of determining the redundancy of the first data stored in the data storage unit 1200 is performed when the first data is received from the host, the operation of determining the redundancy may be omitted during a background operation. Accordingly, the storage device 1000 may reduce the time taken for removing the redundancy of the first data during a background operation.

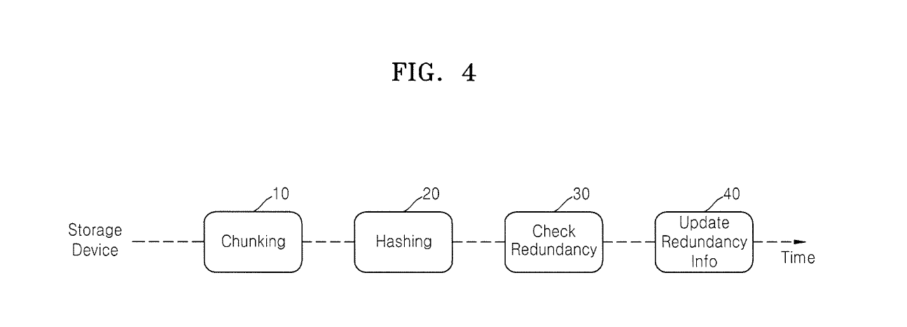

FIG. 4 illustrates an operation of determining data redundancy, performed by the storage device 1000, according to an exemplary embodiment of the present invention. The hashing unit 1110 of FIG. 1 may divide the first data DATA_{—}1 by at least one data unit in operation 10 in a process referred to as chunking. In operation 20, the hashing unit 1110 may use a hash-function to generate a hash value of a data unit that is included in the first data in a process referred to as hashing. As described above, the hash-function used to generate a hash value may be any one of a variety of hash-functions.

The control unit 1130 determines whether a data unit redundant with respect to the data unit that is included in the first data is stored in the data storage unit 1200 by using the hash value generated by the hashing unit 1110 and the hash information stored in the hash information storage unit 1120 in operation 30. That is, the control unit 1130 determines the redundancy of a data unit that is included in the first data. The control unit 1130 may store the redundancy information relating to the data unit in the redundancy information storage unit 1140 according to a result of determining the redundancy of the data unit that is included in the first data in operation 40. As described above, the redundancy information may be updated as redundant data is removed.

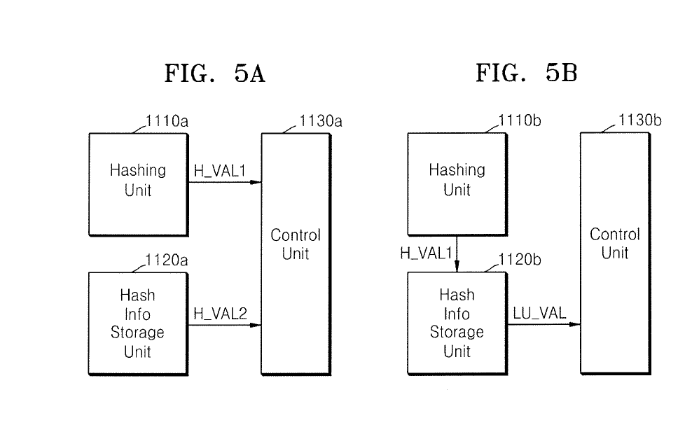

FIGS. 5A and 5B illustrate exemplary embodiments of the hashing unit, the hash information storage unit, and the control unit of FIG. 1. As described above, the hashing unit 1110 of FIG. 1 may use a hash-function to generate a hash value H_VAL1 of a first data unit that is included in first data received from the host. The control unit 1130 of FIG. 1 may determine whether the first data unit is redundant based on the hash value H_VAL1 of the first data unit and the hash information stored in the hash information storage unit 1120.

As shown in FIG. 5A, in an exemplary embodiment, a hashing unit 1110a may output a hash value H_VAL1 of a first data unit to a control unit 1130a. A hash information storage unit 1120a may store at least one hash value for a data unit that is included in data stored in the data storage unit 1200. For example, the hash information storage unit 1120a may store a hash value H_VAL2 of a second data unit that is included in second data stored in the data storage unit 1200, and a control unit 1130a may control the hash information storage unit 1120a to allow the hash information storage unit 1120a to output the hash value H_VAL2 of the second data unit.

In the exemplary embodiment shown in FIG. 5A, the control unit 1130a may use a comparison operation to determine whether the hash value H_VAL1 of the first data unit is identical to the hash value H_VAL2 of the second data unit output from the hash information storage unit 1120a. When the hash value H_VAL1 of the first data unit is different from the hash value H_VAL2 of the second data unit, the control unit 1130a controls the hash information storage unit 1120a to output a hash value of another data unit stored in the hash information storage unit 1120a, and repeatedly performs an operation of comparing the output hash value and the hash value H_VAL1 of the first data unit.

As shown in FIG. 5B, in an exemplary embodiment, a hashing unit 1110b may output a hash value H_VAL1 of a first data unit to a hash information storage unit 1120b. The hash information storage unit 1120b, functioning as a look-up table, may output hash information LU_VAL corresponding to the hash value H_VAL1 of the first data unit input from the hashing unit 1110b, to a control unit 1130b. The control unit 1130b determines whether a data unit having a hash value identical to the hash value H_VAL1 of the first data unit is stored in the data storage unit 1200, based on the hash information LU_VAL input from the hash information storage unit 1120b.

Exemplary embodiments of the hashing unit 1110, the hash information storage unit 1120, and the control unit 1130 are not limited to the exemplary embodiments shown in FIGS. 5A and 5B, and other embodiments for generating a hash value by dividing first data into data units and determining the redundancy of the first data based on the generated hash value and a hash value of a data unit that is included in pre-stored data may be applied to the present invention.

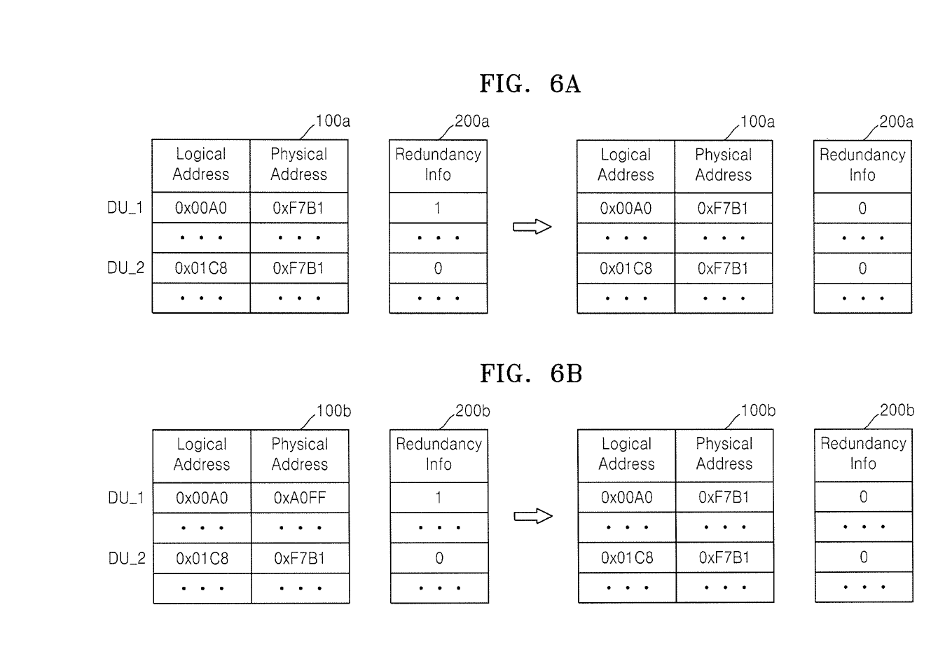

FIGS. 6A and 6B illustrate an operation of removing data redundancy in a storage device, according to an exemplary embodiment of the present invention. A request for writing first data that the host transmits to the storage device 1000 of FIG. 1 may include, for example, an address for the first data. That is, the host may transmit a request for writing the first data to that address to the storage device 1000. Moreover, the storage device 1000 may store the first data at an address different from the address in the host's request when writing the first data to the data storage unit 1200, in order to more efficiently manage stored data. The address in the host's request may be referred to as a logical address, and an address used inside the storage device 1000 may be referred to as a physical address. The logical address and the physical address have a one-to-one correspondence with each other. Information for mapping the logical address and the physical address may be referred to as mapping information. The mapping information may be present in data units that have sizes which are internally defined by the storage device 1000.

According to an exemplary embodiment of the present invention, the storage device 1000 may write or read data and process redundant data by using the mapping information. For example, when two sets of data stored at different logical addresses are identical to each other, and are thus redundant, the storage device 1000 may process the redundant data by using mapping information corresponding to the two data sets. That is, by modifying a physical address included in the mapping information corresponding to one of the two data sets to match a physical address where the other one of the two data sets is actually stored in the storage device 1000, the storage device 1000 may save space where data is stored by removing the redundant data.

FIG. 6A illustrates an operation of removing data redundancy by using the redundancy information storage unit 1140 of the storage device 1000, according to an exemplary embodiment of the present invention. As described above, when the storage device 1000 of FIG. 1 receives a request for writing first data from the host, the control unit 1130 stores the first data in the data storage unit 1200, and determines whether a first data unit DU_{—}1 that is included in the first data is redundant by using the hashing unit 1110 and the hash information storage unit 1120. For example, as shown in FIG. 6A, when it is determined that the first data unit DU_{—}1 that is included in the first data and a second data unit DU_{—}2 that is included in second data stored in the data storage unit 1200 are redundant with respect to each other, the control unit 1130 may modify redundancy information 200a in the redundancy information storage unit 1140 to indicate the redundancy of the first data unit DU_{—}1. For example, in FIG. 6A, the redundancy information 200a includes a single bit that is set to ‘1’ to indicate redundancy. The number and value of bits of the redundancy information 200a is not limited thereto.

In addition, the control unit 1130 may generate the mapping information 100a of the first data unit DU_{—}1 such that it includes the same physical address as the second data unit DU_{—}2. Accordingly, when the host transmits a request for reading a first data unit stored in a logical address “0x00A0”, the storage device 1000 may include data of a second data unit redundant to the first data unit, which is stored at a physical address “0xF7B1”, in a response message to the host's request.

In addition, as shown in FIG. 6A, the control unit 1130 may erase an area in which the first data unit is stored in the data storage unit 1200, and may update redundancy information relating to the first data unit. For example, at the host's request, the control unit 1130 may erase an area in which the first data unit is stored in the data storage unit 1200, and may modify redundancy information 200a in the redundancy information storage unit 1140 to indicate that the data is no longer redundant. For example, in FIG. 6A, the redundancy information 200a may be one bit, and the bit corresponding to the first data unit may be set to ‘0’.

FIG. 6B illustrates an operation of removing data redundancy by using the redundancy information storage unit 1140 of the storage device 1000, according to an exemplary embodiment of the present invention. As described above, when the storage device 1000 of FIG. 1 receives a request for writing first data from the host, the control unit 1130 stores the first data in the data storage unit 1200, and determines whether a first data unit DU_{—}1 that is included in the first data is redundant by using the hashing unit 1110 and the hash information storage unit 1120. For example, as shown in FIG. 6B, when it is determined that the first data unit DU_{—}1 and a second data unit DU_{—}2 that is included in second data stored in the data storage unit 1200 are redundant with respect to each other, the control unit 1130 may modify the redundancy information 200b in the redundancy information storage unit 1140 to indicate the redundancy of the first data unit DU_{—}1. For example, in FIG. 6B, the redundancy information 200b includes a single bit that is set to ‘1’ to indicate redundancy. The number and value of bits of the redundancy information 200b is not limited thereto.

Additionally, the control unit 1130 may store, in an additional storage space, mapping information. The mapping information may include, for example, an address for an area in which the first data unit DU_{—}1 is stored in the data storage unit 1200, as corresponding to the first data unit DU_{—}1. In FIG. 6B, the mapping information includes, for example, “0xA0FF and “0xF7B1.” In contrast to the embodiment shown in FIG. 6A, in the embodiment shown in FIG. 6B, a physical address included in the mapping information corresponding to a first data unit redundant with respect to a second data unit is not changed to match the physical address of the second data unit.

In addition, as shown in FIG. 6B, the control unit 1130 may erase an area in which the first data unit is written in the data storage unit 1200, and may update redundancy information relating to the first data unit. For example, at the host's request, the control unit 1130 may erase an area of the data storage unit 1200 where the first data unit is written, and may modify redundancy information 200b in the redundancy information storage unit 1140 to indicate that the data is no longer redundant. For example, in FIG. 6B, the redundancy information 200b may be one bit, and the bit corresponding to the first data unit may be set to ‘0’. Furthermore, the control unit 1130 may change “0xA0FF” (e.g., a physical address that is included in the mapping information corresponding to the first data unit DU_{—}1) to “0xF7B1” (e.g., a physical address that is included in the mapping information of the second data unit redundant with respect to the first data unit DU_{—}1).

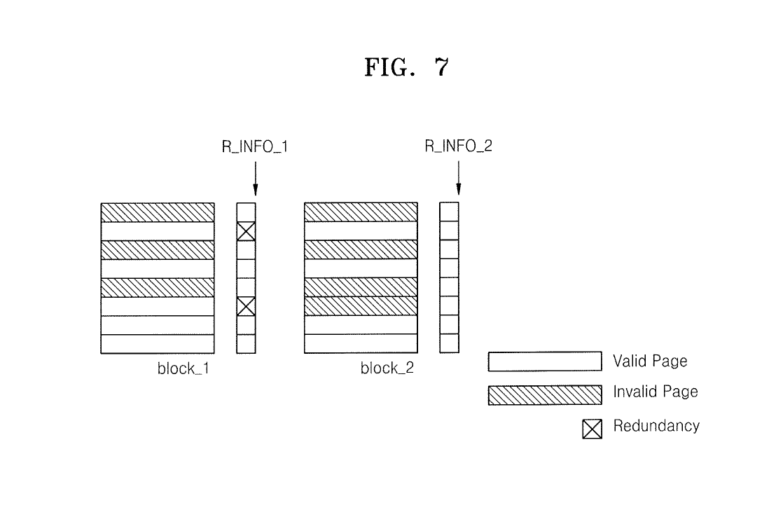

FIG. 7 illustrates an operation of removing data redundancy by using the redundancy information storage unit 1140 of the storage device 1000, according to an exemplary embodiment of the present invention. When the data storage unit 1200 of FIG. 1 is implemented using flash memory, the controller 1100 may function as a memory controller, and the storage device 1000 may be a memory system such as, for example, a memory card or a solid-state drive (SSD). In relation to flash memory, data writing may be performed by a page unit, and data erasing may be performed by a block unit having a size greater than the size of the page unit. Therefore, the memory controller may perform garbage collection on the flash memory. Additionally, since a cell included in the flash memory may only be written to and erased a finite number of times before becoming unreliable, the memory controller may perform wear leveling on the flash memory.

Garbage collection and wear leveling performed by the memory controller may include an operation of copying stored data from one block to another block. At this point, the memory controller may reduce a time for copying data by copying only valid pages from among valid and invalid pages in a block. Accordingly, the memory controller may reduce the time taken for copying data by selecting a block having the smallest number of valid pages among blocks storing data. In such a way, data stored in one block is copied to another block, and then the data still stored in the one block is erased. A block scheduled to be a free block that does not store data may be referred to as a victim block, and a memory controller may select victim blocks through various methods in exemplary embodiments.

According to an exemplary embodiment of the present invention, a unit of data storing redundancy information may be a page of flash memory. For example, as shown in FIG. 7, each of first and second blocks bock_{—}1 and block_{—}2 includes eight pages, and redundancy information R_INFO_{—}1 and R_INFO_{—}2 corresponding to each page may be stored in the redundancy information storage unit 1140.

As shown in the example of FIG. 7, the first block block_{—}1 including a total of eight pages includes five valid pages (indicated by non-shaded blocks) and three invalid pages (indicated by shaded blocks). The first redundancy information R_INFO_{—}1 indicates that two pages among the five valid pages are redundant (indicated by an ‘X’). The second block block_{—}2 including a total of eight pages includes four valid pages and four invalid pages. The second redundancy information R_INFO_{—}2 indicates that the second block block_{—}2 does not include a redundant page.

If redundancy information R_INFO_{—}1 and R_INFO_{—}2 for each page is not provided, since the number of valid pages in the second block block_{—}2 is less than the number of valid pages in the first block block_{—}1, the memory controller selects the second block block_{—}2 as a victim block, and changes the second block block_{—}2 to a free block through operations of copying the four valid pages and then erasing the second block block_{—}2.

However, if redundancy information R_INFO_{—}1 and R_INFO_{—}2 for each page is provided, although the first block block_{—}1 includes five valid pages, two of the valid pages are redundant, and data stored in those two valid pages are already stored in another page of the flash memory. Thus, the first block block_{—}1 may become a free block by copying the three valid pages that are not redundant to another block. Therefore, according to an exemplary embodiment of the present invention, the memory controller selects the first block block_{—}1 as a victim block instead of the second block block_{—}2 as a result of the use of the redundancy information of the valid pages, which may reduce the time taken for generating a free block. Furthermore, the memory controller may simultaneously, or substantially simultaneously remove redundant pages through garbage collection or wear leveling.

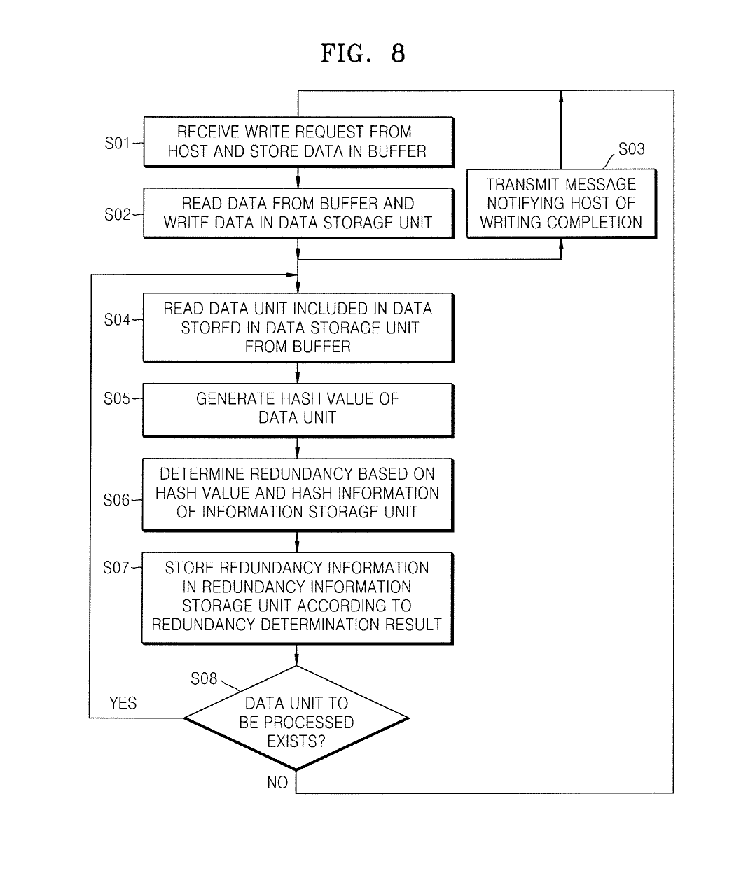

FIG. 8 is a flowchart illustrating a method of removing data redundancy in a storage device, according to an exemplary embodiment of the present invention. At block S01, the storage device may receive a request for writing data from a host, and the data may be stored in a buffer of the storage device. At block S02, a control unit reads the data stored in the buffer and then writes the read data in a data storage unit. The control unit writes the data to the data storage unit, and at block S03, transmits a message to the host notifying the host that the data writing operation has been completed. The storage device may then return to block S01 to receive a new request from the host.

A hashing unit may read a data unit that is included in data already stored in the data storage unit from the buffer at block S04. The hashing unit may generate a hash value for the read data unit at block S05. The control unit determines whether the data unit is redundant based on the hash value generated by the hashing unit and hash information stored in a hash information storage unit at block S06. The control unit may store the redundancy information of the data unit in the redundancy information storage unit according to a determination result indicating whether the data unit is redundant at block S07. The control unit determines whether there are data units whose redundancy is not yet determined among data units that are included in data received from the host and stored in the data storage unit at block S08. If there are data units whose redundancy has not yet been determined, the control unit reads a new data unit from the buffer at block S04.

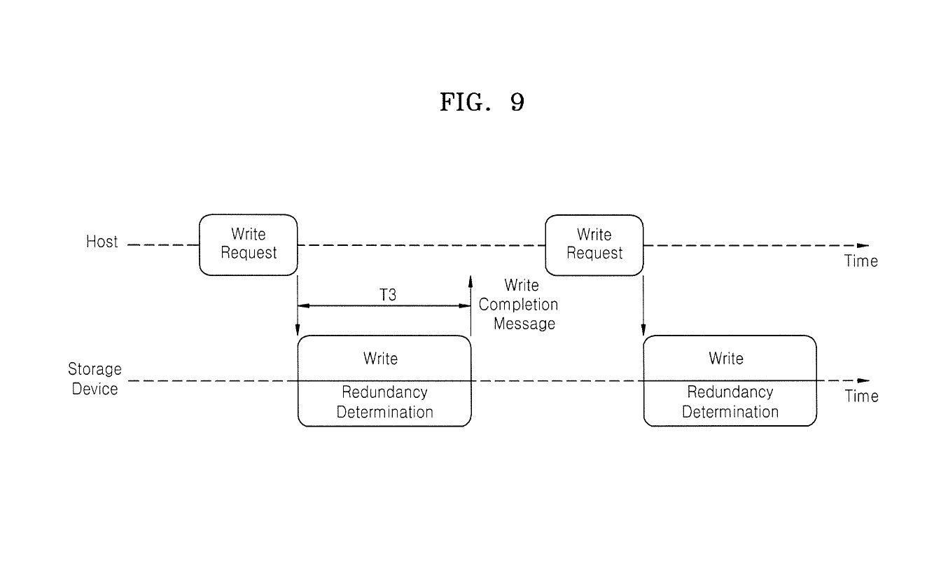

FIG. 9 illustrates a method of determining data redundancy in the storage device 1000, according to an exemplary embodiment of the present invention. According to an exemplary embodiment of the present invention, upon receiving a request for writing first data from a host, the storage device 1000 of FIG. 1 writes the first data and transmits a message to the host notifying the host that the data writing operation has completed. Additionally, the storage device 1000 may perform an operation that writes the first data and an operation that determines whether the first data is redundant in parallel with writing the first data. That is, in contrast to the method of removing data redundancy as shown in FIG. 3, in the exemplary embodiment of FIG. 9, an operation of determining the redundancy of the first data and an operation of writing the first data may be simultaneously, or substantially simultaneously performed.

In certain situations, writing the first data stored in the storage device 1000 of FIG. 1 to the data storage unit 1200 may take a relatively long time. Accordingly, in an exemplary embodiment of the present invention, the control unit 1130 may simultaneously, or substantially simultaneously, perform an operation of determining whether the first data unit that is included in the first data is redundant by using the hashing unit 1110 and the hash information storage unit 1120 in parallel with an operation of writing the first data to the data storage unit 1200, and then performing a subsequent operation of storing the redundancy information of the first data unit in the redundancy information storage unit 1140 according to a determination result. The response time of the storage device 1000 may include a time for simultaneously, or substantially simultaneously determining whether the first data unit that is included in the first data is redundant and writing the first data, and is indicated by T3 in FIG. 9. During an idle time, the control unit 1130 may perform an operation of removing the redundancy of the first data based on a determination result regarding whether the first data is redundant. The process of simultaneously determining whether data is redundant and writing data may be repeated, as shown in FIG. 9

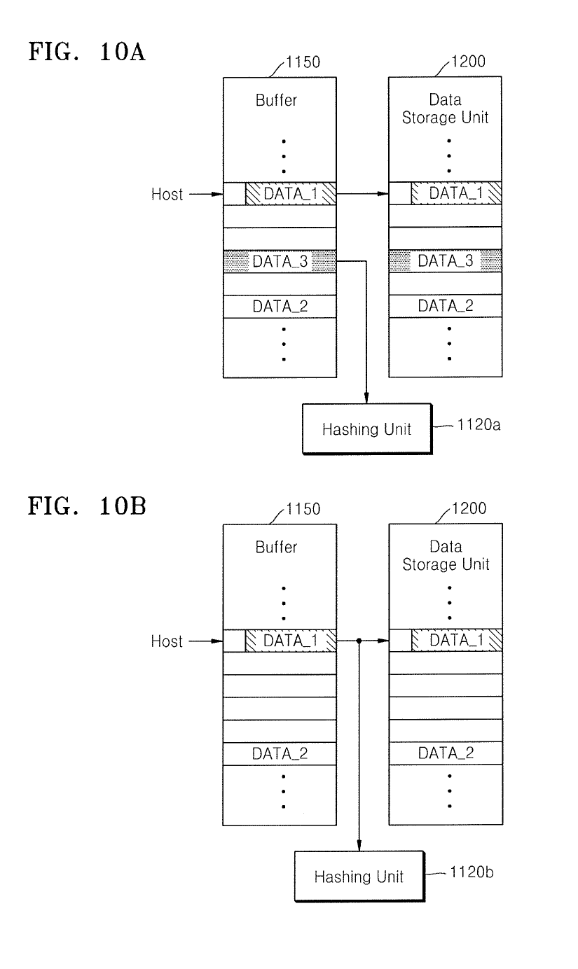

FIGS. 10A and 10B illustrate a comparison of the methods of removing data redundancy in the storage device 1000 shown in FIGS. 3A and 3B, and FIG. 9, according to exemplary embodiments of the present invention. According to the exemplary embodiments of the present invention shown in FIGS. 3A and 3B, and FIG. 9, data units whose redundancy is determined by the control unit 1130 through the hashing unit 1110 and the hash information storage unit 1120 may be different.

FIG. 10A illustrates a method of determining data redundancy in the storage device 1000 shown in FIGS. 3A and 3B, according to an exemplary embodiment of the present invention. The control unit 1130 may read the first data DATA_{—}1, which is input from the host, from the buffer 1150, and then may store the read first data DATA_{—}1 in the data storage unit 1200. While the control unit 1130 writes the first data DATA_{—}1 to the data storage unit 1200, the hashing unit 1120a reads a data unit that is included in the third data DATA 3, and then generates the hash value of the read data unit. The third data DATA_{—}3 is received from the host prior to receipt of the first data DATA_{—}1 and is already stored in the data storage unit 1200. The control unit 1130 simultaneously, or substantially simultaneously controls an operation of writing the first data DATA_{—}1 to the data storage unit 1200 and performs an operation of determining whether the third data DATA_{—}3 is redundant by using a hash value that the hashing unit 1120a generates.

FIG. 10B illustrates a method of determining data redundancy in the storage device 1000 shown in FIG. 9, according to an exemplary embodiment of the present invention. Similar to FIG. 10A, the control unit 1130 may read the first data DATA_{—}1, which is input from the host, from the buffer 1150, and then may store the read first data DATA_{—}1 in the data storage unit 1200. The hashing unit 1120b may receive the first data DATA_{—}1 that is read by the control unit 1200 in order to write the first data DATA_{—}1 to the data storage unit 1200. The hashing unit 1120b may generate a hash value for the first data unit that is included in the input first data DATA_{—}1, and the control unit 1130 may simultaneously, or substantially simultaneously perform an operation of writing the first data DATA_{—}1 by using the hash value generated by the hashing unit 1120b and perform an operation of determining whether the first data DATA_{—}1 is redundant (e.g., these operations may be performed in parallel).

FIG. 11 is a block diagram illustrating a computing system 2000 including a storage device 2400 and a host, according to an exemplary embodiment of the present invention. The storage device 2400 may be installed on the computing system 2000, and the computing system 2000 may be, for example, a mobile device, a desktop computer, or a server, however the computing system 2000 is not limited thereto.

The computing system 2000 includes a central processing unit (CPU) 2100, RAM 2200, a user interface 2300, and the storage device 2400, which are electrically connected to each other through a bus 2500. The host in the computing system 2000 may include, for example, the CPU 2100, the RAM 2200, and the user interface 2300. The CPU 2100 controls the computing system 2000 and performs a calculation operation corresponding to a user's command input through the user interface 2300. The RAM 2200 may serve as a data memory of the CPU 2100. The CPU 2100 may write or read data to or from the storage device 2400 as the host.

When the computing system 2000 is a server, the storage device 2400 may serve as a backup storage device storing backup data, however the storage device 2400 is not limited thereto. When the storage device 2400 is used as a backup storage device, the host may require a large capacity storage device, and the storage device 2400 may secure a sufficient storage space by processing data redundancy and storing data.

As in the above exemplary embodiments, the storage device 2400 may include, for example, a buffer, a hashing unit, a hash information storage unit, a control unit, a redundant information storage unit, and a data storage unit. The buffer may temporarily store data received from the host. The hashing unit may generate a hash value of a data unit that is included in data. The hash information storage unit may store hash information relating to data units that is included in data stored in the data storage unit. The control unit may control an operation of writing data to the data storage unit. The hashing unit may determine whether data is redundant by using the hash value generated by the hashing unit and hash information that the hash information storage unit stores, and may also remove redundant data stored in the data storage unit.

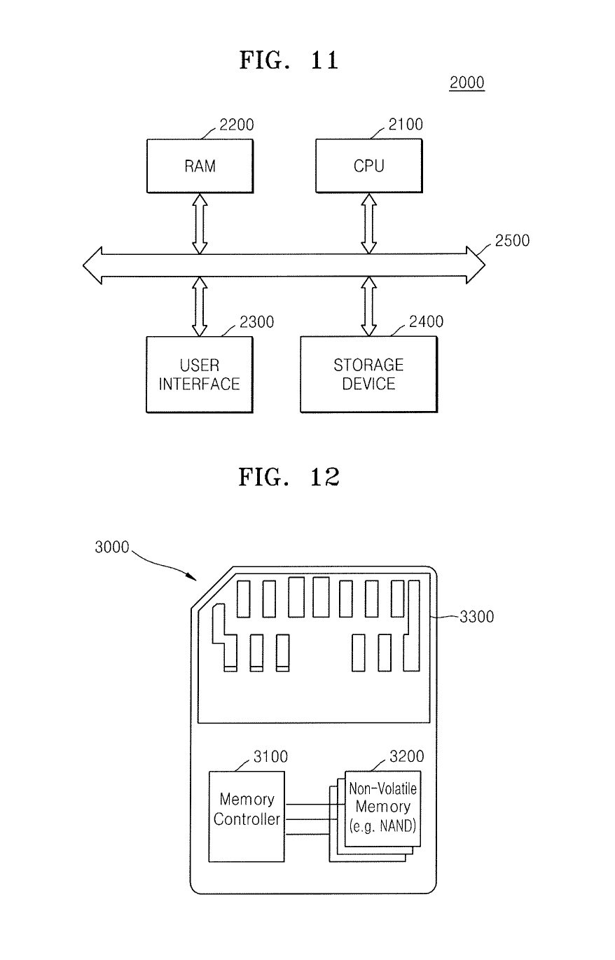

FIG. 12 is a block diagram of a memory card 3000, according to an exemplary embodiment of the present invention. A storage device according to the exemplary embodiments of the present invention described above may be the memory card 3000. For example, the memory card 3000 may be an embedded MultiMedia Card (eMMC) or a Secure Digital (SD) card, however the memory card 3000 is not limited thereto. As shown in FIG. 12, the memory card 3000 may include, for example, a memory controller 3100, nonvolatile memory 3200, and a connection area 3300.

The memory controller 3100 may perform a method of removing data redundancy in a storage device according to the exemplary embodiments of the present invention. The memory controller 3100 may communicate with a host according to a predetermined protocol through the connection area 3300. The protocol may be, for example, an eMMC or SD protocol, SATA, SAS or USB, however the protocol is not limited thereto. The nonvolatile memory 3200 may include a cell that retains data even when no power is supplied. For example, the nonvolatile memory 3200 may include flash memory, Magnetic Random Access Memory (MRAM), Resistance RAM (RRAM), Ferroelectric RAM (FRAM), or Phase Change Memory (PCM), however the nonvolatile memory 3200 is not limited thereto.

While the present invention has been particularly shown and described with reference to the exemplary embodiments thereof, it will be understood by those of ordinary skill in the art that various changes in form and detail may be made therein without departing from the spirit and scope of the present invention as defined by the following claims.

What is claimed is:

1. A method of processing data in a storage device, comprising:
writing first data to a data storage unit of the storage device upon receiving the first data from an external host of the storage device;
outputting a message to the external host indicating completion of writing the first data to the data storage unit; and
determining whether a first data unit included in the first data is redundant in the data storage unit, wherein determining whether the first data unit is redundant is performed subsequent to or in parallel with writing the first data to the data storage unit.

2. The method of claim 1, wherein determining whether the first data unit is redundant comprises:
generating a hash value of the first data unit;
determining whether the first data unit is redundant based on the hash value of the first data unit and information relating to a hash value of a second data unit included in second data received prior to the first data and stored in the data storage unit; and
writing redundancy information corresponding to the first data unit and indicating whether the first data unit is redundant to a redundancy information storage unit of the storage device according to a result of determining whether the first data unit is redundant.

3. The method of claim 2, further comprising:
modifying a physical address of mapping information corresponding to the first data unit to be identical to a physical address of mapping information corresponding to the second data unit upon determining that the first data unit is redundant with respect to the second data unit.

4. The method of claim 2, further comprising:
performing garbage collection or wear leveling in an invalid area of the data storage unit in which the first data unit is stored upon determining that the first data unit is redundant based on the redundancy information corresponding to the first data unit,
wherein the data storage unit comprises flash memory.

5. The method of claim 2, further comprising performing a deduplication operation, wherein the deduplication operation comprises:
erasing an area in which the first data unit is stored in the data storage unit based on the redundancy information corresponding to the first data unit; and
updating the redundancy information corresponding to the first data unit.

6. The method of claim 5, wherein performing the deduplication operation further comprises:
changing a physical address of mapping information corresponding to the first data unit to a physical address of mapping information corresponding to the second data unit upon determining that the first data unit is redundant with respect to the second data unit.

7. The method of claim 5, wherein the deduplication operation progresses to additional data units when a request from the external host is not pending after outputting the message and after determining whether the first data unit is redundant.

8. The method of claim 1, wherein additional operations are not performed between writing the first data to the data storage unit and determining whether the first data unit is redundant, when determining whether the first data unit is redundant is performed subsequent to writing the first data to the data storage unit.

9. A storage device, comprising:
a hashing unit configured to generate a hash value of a first data unit included in first data received from an external host;
a data storage unit configured to store second data received prior to the first data;
a hash information storage unit configured to store information relating to a hash value of at least one second data unit included in the second data;
a redundancy information storage unit configured to store redundancy information corresponding to the at least one second data unit and indicating whether the at least one second data unit is redundant; and
a control unit configured to determine redundancy of the first data unit upon receiving the first data from the external host, wherein determining the redundancy of the first data unit is performed subsequent to or in parallel with writing the first data to the data storage unit,
wherein determining the redundancy of the first data unit comprises determining whether the first data unit is redundant based on the information relating to the hash value of the at least one second data unit and the hash value of the first data unit,
wherein the control unit is further configured to write redundancy information corresponding to the first data unit and indicating whether the first data unit is redundant to the redundancy information storage unit upon determining the redundancy of the first data unit.

10. The storage device of claim 9, wherein the control unit is further configured to erase an area in which the first data unit is stored in the data storage unit based on the redundancy information corresponding to the first data unit, and perform a deduplication operation comprising updating the redundancy information corresponding to the first data unit.

11. The storage device of claim 10, wherein the control unit is configured to perform the deduplication operation when a request from the external host is not pending after storing the second data and determining the redundancy of the first data unit.

12. The storage device of claim 10, wherein the control unit is further configured to change a physical address of mapping information corresponding to the first data unit to a physical address of mapping information corresponding to the at least one second data unit while determining the redundancy of the first data unit, upon determining that the first data unit is redundant.

13. The storage device of claim 10, wherein the control unit is further configured to change a physical address of mapping information corresponding to the first data unit to a physical address of mapping information corresponding to the at least one second data unit during the deduplication operation, upon determining that the first data unit is redundant with respect to the at least one second data unit.

14. The storage device of claim 9, wherein the data storage unit comprises flash memory, and the control unit is further configured to perform garbage collection or wear leveling in an invalid area of the flash memory in which the first data unit is stored upon determining that the first data unit is redundant based on the redundancy information corresponding to the first data unit.

15. The storage device of claim 9, wherein the control unit is further configured to store information relating to the hash value of the first data unit in the hash information storage unit while determining the redundancy of the first data unit upon determining that the first data unit is not redundant.

16. The storage device of claim 9, wherein the redundancy information storage unit is further configured to store size information of the first data unit and the at least one second data unit.

17. The storage device of claim 9, wherein additional operations are not performed between writing the first data to the data storage unit and determining whether the first data unit is redundant, when determining whether the first data unit is redundant is performed subsequent to writing the first data to the data storage unit.

18. A method of processing data in a storage device, comprising:
writing first data to a data storage unit of the storage device upon receiving the first data from an external host of the storage device;
determining whether a first data unit included in the first data is redundant in the data storage unit, wherein determining whether the first data unit is redundant is performed subsequent to or simultaneous with writing the first data to the data storage unit; and
removing the first data unit from the data storage unit during an idle time of the storage device upon determining that the first data unit is redundant, wherein a request from the external host is not pending during the idle time.

19. The method of claim 18, wherein additional operations are not performed between writing the first data to the data storage unit and determining whether the first data unit is redundant, when determining whether the first data unit is redundant is performed subsequent to writing the first data to the data storage unit.

20. The method of claim 18, wherein determining whether the first data unit is redundant comprises:
generating a hash value of the first data unit;
determining whether the first data unit is redundant based on the hash value of the first data unit and information relating to a hash value of a second data unit included in second data received prior to the first data and stored in the data storage unit; and
writing redundancy information corresponding to the first data unit and indicating whether the first data unit is redundant to a redundancy information storage unit of the storage device according to a result of determining whether the first data unit is redundant.
